(19) United States
(12) Patent Application Publication
(10) Pub. No.: US 2012/0306576 A1
(43) Pub. Date: Dec. 6, 2012

(54) METHOD AND SYSTEM FOR IMPROVING LINEARITY OF AN AMPLIFIER BY MEANS OF IM3 CANCELATION

(76) Inventors: Vamsi Paidi, Irvine, CA (US); Masoud Koochakzadeh, Vista, CA (US)

(21) Appl. No.: 13/485,039

(22) Filed: May 31, 2012

Related U.S. Application Data
(60) Provisional application No. 61/492,775, filed on Jun. 2, 2011.

(51) Int. Cl. H03F 3/16

(52) U.S. Cl. 330/277

(57) ABSTRACT

An amplifier for providing improved third-order intermodulation (IM3) cancelation. The amplifier may comprise a main branch for amplifying input signals and an auxiliary branch for generating IM3 signals that are equal to corresponding IM3 components resulting from amplifying input signals via the main branch, with both of the main and the auxiliary branches being configured as differential circuits. The differential implementation may result in the auxiliary branch generating IM3 distortion signals with minimal or no non-IM3 signals. Each of the main and the auxiliary branches may comprise at least two transistor elements. Separate bias current sources may be applied to each of the main and the auxiliary branches. Operation of the auxiliary branch may be controlled by adjusting one or both of the bias current sources. Outputs of the main and the auxiliary branches may be cross-coupled, to invert a sign of IM3 distortion signals generated via the auxiliary branch.

### CLAIM OF PRIORITY

This patent application makes reference to, claims priority to and claims benefit from U.S. Provisional Application Ser. No. 61/492,775 filed on Jun. 2, 2011.

The above stated application is hereby incorporated herein by reference in its entirety.

### INCORPORATION BY REFERENCE

This application also makes reference to:
U.S. Provisional Patent Application Ser. No. 61/610,550 filed on Mar. 14, 2012;
U.S. Provisional Patent Application Ser. No. 61/433,933 filed on Jan. 18, 2011; and
U.S. patent application Ser. No. 13/351,071 filed on Jan. 16, 2012.

Each of the above stated applications is hereby incorporated herein by reference in its entirety.

### FEDERALLY SPONSORED RESEARCH OR DEVELOPMENT

[Not Applicable].

### MICROFICHE/COPYRIGHT REFERENCE

[Not Applicable].

### FIELD OF THE INVENTION

Certain embodiments of the invention relate to communications. More specifically, certain embodiments of the invention relate to a method and a system for improving linearity of an amplifier by means of third-order intermodulation (IM3) cancelation.

### BACKGROUND OF THE INVENTION

Data, including content communicated over broadband connections, may typically be carried using signals transmitted over wireless and/or wired connections. Therefore, communicated data must be extracted from received signals at the receiving system. Reception of the signals and processing thereof, however, may introduce errors and/or distortion which may affect the extraction of communicated data. The error and/or distortion may be caused by nonlinearity exhibited by the receiving system, and/or by various components thereof that are utilized during reception, and/or handling or processing of the received signals.

Further limitations and disadvantages of conventional and traditional approaches will become apparent to one of skill in the art, through comparison of such systems with some aspects of the present invention as set forth in the remainder of the present application with reference to the drawings.

### BRIEF SUMMARY OF THE INVENTION

A system and/or method is provided for improving linearity of an amplifier by means of third-order intermodulation (IM3) cancelation, substantially as shown in and/or described in connection with at least one of the figures, as set forth more completely in the claims.

These and other advantages, aspects and novel features of the present invention, as well as details of an illustrated embodiment thereof, will be more fully understood from the following description and drawings.

### BRIEF DESCRIPTION OF SEVERAL VIEWS OF THE DRAWINGS

FIG. 1 is a block diagram illustrating an exemplary electronic device, which may be used in accordance with an embodiment of the invention.

FIG. 2 is a block diagram illustrating an exemplary amplifier that may provide third-order intermodulation (IM3) cancelation, in connection with an embodiment of the invention.

FIG. 3 is a block diagram illustrating an exemplary amplifier that may provide third-order intermodulation (IM3) cancelation, in accordance with an embodiment of the invention.

FIG. 4 is a diagram illustrating exemplary transconductance functions for main and auxiliary paths of an amplifier configured for optimized IM3 cancelation, and a corresponding total transconductance function for the amplifier, in connection with an embodiment of the invention.

FIG. 5 is a flow chart that illustrates exemplary optimized IM3 cancelation, in accordance with an embodiment of the invention.

### DETAILED DESCRIPTION OF THE INVENTION

Certain embodiments of the invention may be found in a method and system for improving linearity of an amplifier by means of third-order intermodulation (IM3) cancelation. In various embodiments of the invention, an amplifier may be used in providing improved third-order intermodulation (IM3) cancelation. The amplifier may comprise a main branch for amplifying input signals, and an auxiliary branch for generating IM3 signals which may be equal in value to corresponding IM3 components resulting when amplifying input signals via the main branch. Furthermore, both of the main branch and the auxiliary branch may be configured in accordance with differential circuit topology. In this regard, the differential circuit topology may result in the auxiliary branch being operable to generate IM3 distortion signals with minimal (or no) non-IM3 signals, especially signals that may affect second-order intercept point (IIP2) processing. Sign of IM3 distortion signals generated via the auxiliary branch may be inverted to provide the desired IM3 cancelation. In this regard, outputs of the main branch and the auxiliary branch may be cross-coupled, to invert the sign of the IM3 distortion signals generated via the auxiliary branch. Each of the main branch and the auxiliary branch may comprise at least two transistor elements. In this regard, the transistor elements used in the main branch and/or the auxiliary branch may comprise transistors comprises NMOS transistors, PMOS transistors, and/or CMOS transistors. The same approach, however, may be applied to other gain element, such as when combining transistors with resistors. In addition, separate bias current sources may be applied to each of the main branch and the auxiliary branch. The transistors and/or the bias current source used in each of the main branch and the auxiliary branch may be selected adaptively, to ensure the optimal IM3 cancelation performance with the least impact on non-IM3 performance in the amplifier. Furthermore, operation of the auxiliary branch may be controlled by adjusting one or both of the bias current sources.

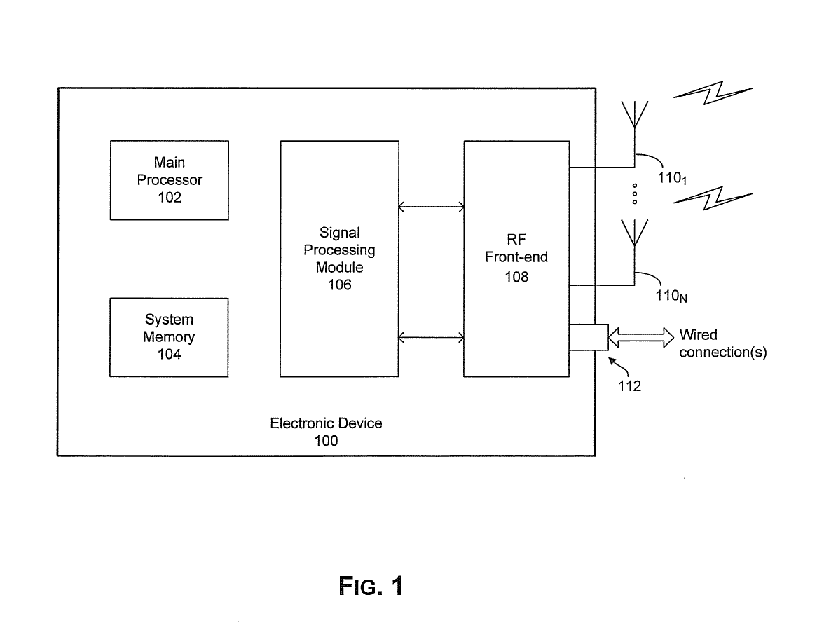

FIG. 1 is a block diagram illustrating an exemplary electronic device, which may be used in accordance with an embodiment of the invention. Referring to FIG. 1 there is shown an electronic device 100.

The electronic device 100 may comprise suitable logic, circuitry, interfaces, and/or code that may be operable to implement various aspects of the invention. In this regard, the electronic device may support communication over wired and/or wireless connections. For example, the electronic device 100 may support a plurality of wired and/or wireless interfaces and/or protocols, and may be operable to perform necessary processing operations to facilitate transmission and/or reception of signals (e.g. RF signals) over supported wired and/or wireless interfaces. Exemplary electronic devices may comprise cellular/smart phones or similar handheld devices, tablets, desktop computers, laptops computers, servers, personal media players, set top boxes or broadband receivers, and/or other like devices. Exemplary wireless protocols or standards that may be supported and/or used by the electronic device 100 may comprise wireless personal area network (WPAN) protocols, such as Bluetooth (IEEE 802.15); wireless local area network (WLAN) protocols, such as WiFi (IEEE 802.11); cellular standards, such as 2G/2G+ (e.g., GSM/GPRS/EDGE) and 3G/3G+ (e.g., CDMA2000, UMTS, HSPA); 4G standards, such as WiMAX (IEEE 802.16) and LTE; Ultra-Wideband (UWB); and/or wireless TV/broadband (access) standards, such as terrestrial and/or satellite TV standards (e.g., DVB-T/T2, DVB-S/S2). Exemplary wired protocols and/or interfaces that may be supported and/or used by the electronic device 100 may comprise Ethernet (IEEE 802.3), Fiber Distributed Data Interface (FDDI), Integrated Services Digital Network (ISDN); and/or wired based TV/broadband (access) standards, such as Digital Subscriber Line (DSL), Data Over Cable Service Interface Specification (DOCSIS), Multimedia over Coax Alliance (MoCA).

The electronic device 100 may comprise, for example, a main processor 102, a system memory 104, a signal processing module 106, a radio frequency (RF) front-end 108, a plurality of antennas 110₁-110_{N}, and one or more wired connectors 112. The main processor 102 may comprise suitable logic, circuitry, interfaces, and/or code that may be operable to process data, and/or control and/or manage operations of the electronic device 100, and/or tasks and/or applications performed therein. In this regard, the main processor 102 may be operable to configure and/or control operations of various components and/or subsystems of the electronic device 100, by utilizing, for example, one or more control signals. The main processor 102 may enable execution of applications, programs and/or code, which may be stored in the system memory 104, for example. The system memory 104 may comprise suitable logic, circuitry, interfaces, and/or code that may enable permanent and/or non-permanent storage, buffering, and/or fetching of data, code and/or other information, which may be used, consumed, and/or processed in the electronic device 100. In this regard, the system memory 104 may comprise different memory technologies, including, for example, read-only memory (ROM), random access memory (RAM), Flash memory, solid-state drive (SSD), and/or field-programmable gate array (FPGA). The system memory 104 may store, for example, configuration data, which may comprise parameters and/or code, comprising software and/or firmware.

The signal processing module 106 may comprise suitable logic, circuitry, interfaces, and/or code for enabling processing of signals transmitted and/or received by the electronic device 100. The signal processing module 106 may be operable to perform such signal processing operation as filtering, amplification, up-convert/down-convert baseband signals, analog-to-digital and/or digital-to-analog conversion, encoding/decoding, encryption/decryption, and/or modulation/demodulation.

The RF front-end 108 may comprise suitable logic, circuitry, interfaces, and/or code that may be operable to perform RF transmission and/or reception during wireless and/or wired communications, such over a plurality of supported RF bands and/or carriers. The RF front-end subsystem 108 may be operable to perform, for example, wireless communications of RF signals via the plurality of antennas 110₁-110_{N}. Each of the plurality of antennas 110₁-110_{N} may comprise suitable logic, circuitry, interfaces, and/or code that may enable transmission and/or reception of RF signals within certain bandwidths and/or based on certain protocols. The RF front-end subsystem 108 may be operable to perform wired communications of RF signals via the plurality of connectors 112. The wired connectors 112 may comprise suitable logic, circuitry, interfaces, and/or code that may enable transmission and/or reception of RF signals over wired connections, within certain bandwidths and/or based on certain protocols (e.g., MoCA).

In operation, the electronic device 100 may be operable to perform wired and/or wireless communication, in accordance with one or more interfaces and/or protocols supported thereby. In this regard, the electronic device 100 may be operable to transmit and/or receive RF signals over supported wired and/or wireless interfaces, using the RF front-end 108, and to perform necessary signal processing operations to facilitate such transmission/reception, using the signal processing module 106. The RF signals transmitted and/or received by the electronic device 100 may carry data pertaining to applications running in the electronic device 100.

In some instances, the electronic device 102 (and/or components thereof) may exhibit nonlinear behavior, which may comprise static and/or dynamic nonlinearity characteristics, such as during reception/transmission of signals and/or handling thereof. For example, nonlinearity may be introduced by amplification performed during handling and/or processing of signals, via the signal processing module 106 and/or the RF front-end 108. Such nonlinear behavior may result in errors or distortion to data communicated via the handled signals, thus causing degradation or corruption to data communication to and/or from the electronic device 100.

One particular type of nonlinear distortion that may be occur during various signal processing operations, such as, for example, during amplification operations, may comprise intermodulation (IM) distortion, which may occur during handling of signals containing multiple different frequencies in a nonlinear system. Intermodulation may be related to one characteristic of nonlinear systems, that it, they typically generate harmonics. In this regard, where input to the nonlinear system is a signal of a single frequency, the output may be a signal which includes, in addition to the input frequency, a number of integer multiples of the input frequency (i.e., harmonics). Intermodulation may occur, however, when the input to the nonlinear system is composed of two or more frequencies (which may be known as fundamental frequencies), whereby the output may contain in addition to the frequencies of the input signal (the fundamental frequencies) and their harmonics, a number of non-harmonic frequencies resulting from sum and difference products, of various order, of all of the harmonics and the fundamentals and between each other.

In this regard, the 1st order of intermodulation may correspond to the linear output. Furthermore, because in most instances, even-order IM distortion components may ideally be zero, and because odd-order IM distortion components beyond the 3rd order distortion component are negligible, then the 3rd order intermodulation (IM3) distortion may represent the main intermodulation distortion in the system, and cancelling the IM3 distortion would essentially remove the IM distortion introduced by the nonlinearity of the system.

Accordingly, in various embodiments of the invention, linearity of amplification components, such as those used within the signal processing module 106 of the electronic device 100, may be improved by means of IM3 cancelation. In particular, the IM3 cancelation may be performed in a manner that enables cancelling IM3 distortion components without degrading the system performed with respect to other IM components, such as, for example, second-order intermodulation components. This is explained in more detail with respect to at least some of the following figures.

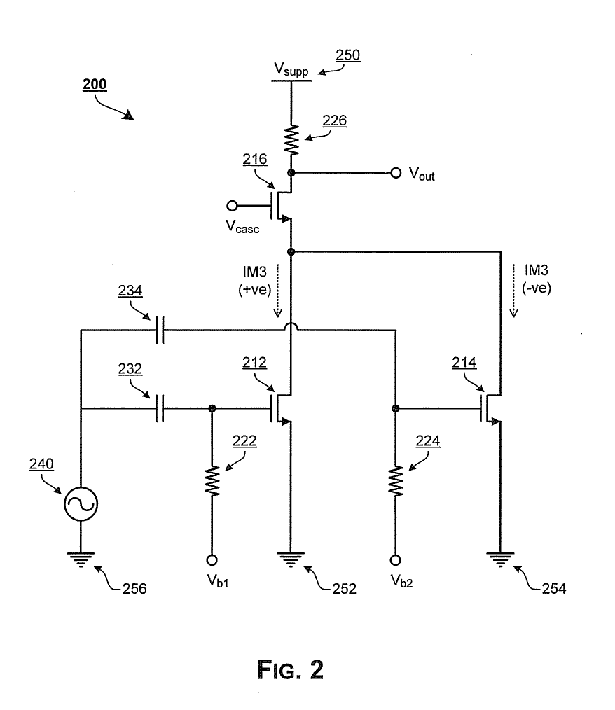

FIG. 2 is a block diagram illustrating an exemplary amplifier that may provide third-order intermodulation (IM3) cancelation, in connection with an embodiment of the invention. Referring to FIG. 2, there is shown an amplifier 200.

The amplifier 200 may comprise suitable logic, circuitry, code, and/or interfaces operable to amplify signals. In this regard, the amplifier 200 may provide the amplification by controlling and/or adjusting its output, which may be drawn from a power supply, so as to match the input signal (typically a voltage or a current) in shape but with larger amplitude (i.e., with particular gain). In this sense, an amplifier may be considered as modulating the output of the power supply. The amplifier 200, as shown in FIG. 2, may provide third-order intermodulation (IM3) cancelation. In this regard, the amplifier 200 may be implemented with a traditional topology (as described herein), which while providing the desired IM3 cancelation, may result in degradation in system perform with respect to other IM components.

The amplifier 200 may comprise transistors 212, 214, and 216, resistors 222, 224, and 226, capacitors 232 and 234; main voltage supply (Vₛᵤₚₚ) 250, and grounds 252 and 254. The transistors 212, 214, and 216 may comprise n-type MOS (NMOS), p-type MOS (PMOS), or complementary MOS (CMOS) transistor elements. The invention is not limited, however, to circuits based on (only) transistor elements, and may be used in substantially similar manner in circuit incorporating other types of gain elements, such as with gain elements combining transistors with resistors for example.

The amplifier 200 may be implemented as a cascode amplification circuit, where the transistor 216 may be utilized for the cascoding stage. Cascoding may be utilized to allow improving input-output isolation as there is no direct coupling from the output to input. In this regard, the drain of transistor 216 may be coupled (through resistor 226) to the Vₛᵤₚₚ 250, with cascode voltage (V_{casc}) being applied to gate of the transistor 216, with the value of V_{casc} being selected to achieve the best isolation.

The amplifier 200 may be utilized to amplify input signals, corresponding to input AC voltage (Vᵢₙ) 240 for example. In this regard, the amplification performed via the amplifier 200 may comprise utilizing the Vᵢₙ 240 in controlling and/or adjusting modulating the output of the power supply of the amplifier 200, corresponding to the Vₛᵤₚₚ 250, such that the resultant Vₒᵤₜ may match Vᵢₙ 240 in shape but have higher amplitude, thus applying gain to the input signal. The capacitors 232 and 234 may be used to regulate and control inputting of signals into the amplifier 200. For example, the capacitors 232 and 234 may allow the AC input signal—i.e., corresponding to Vᵢₙ 240—to pass while blocking the DC voltage established within the amplifier 200, so that any preceding circuit may not be affected by the internal DC voltage of the amplifier 200.

In some instances, in addition to providing amplification, the amplifier 200 may also provide third-order intermodulation (IM3) cancelation. The amplification and IM3 cancelation may be performed via transistors 212 and 214. For example, the input signal corresponding to Vᵢₙ 240, along with bias voltage V_{b1} and resistor 222 for transistor 212, and with bias voltage V_{b2} and resistor 224 for transistor 214, may be utilized in controlling the amplification performed via transistor 212, and the IM3 cancelation performed via transistor 214. In this regard, bias voltages V_{b1} and V_{b2} (and resistors 222 and 224) may be chosen such that transistors 212 and 214 may generate, while amplifying the input signals, an IM3 distortion with equal value but opposite polarity. In particular, when bias voltages V_{b1} and V_{b2} are selected and set properly, an IM3 distortion signal may be generated via the transistor 214 with the same value of the IM3 component of the amplification performed via transistor 212, but with inverted sign—e.g., −ve for the IM3 distortion signal corresponding to +ve of the IM3 component. The IM3 distortion signal may then be used to cancel out the IM3 component generated during the amplification, thus resulting in improved third-order intermodulation intercept point (IIP3) performance.

Use of a traditional topology based approach, however, may result in degraded second-order intermodulation intercept point (IIP2) performance, because during generation of IM3 distortion signal (−ve) via transistor 214, IM2 distortion signals may also be produced, which may also be equal in value to the IM2 components generated via the transistor 212, but with the same sign. Thus, the IM2 distortion component may actually be doubled, and if so, IIP2 performance would be degraded.

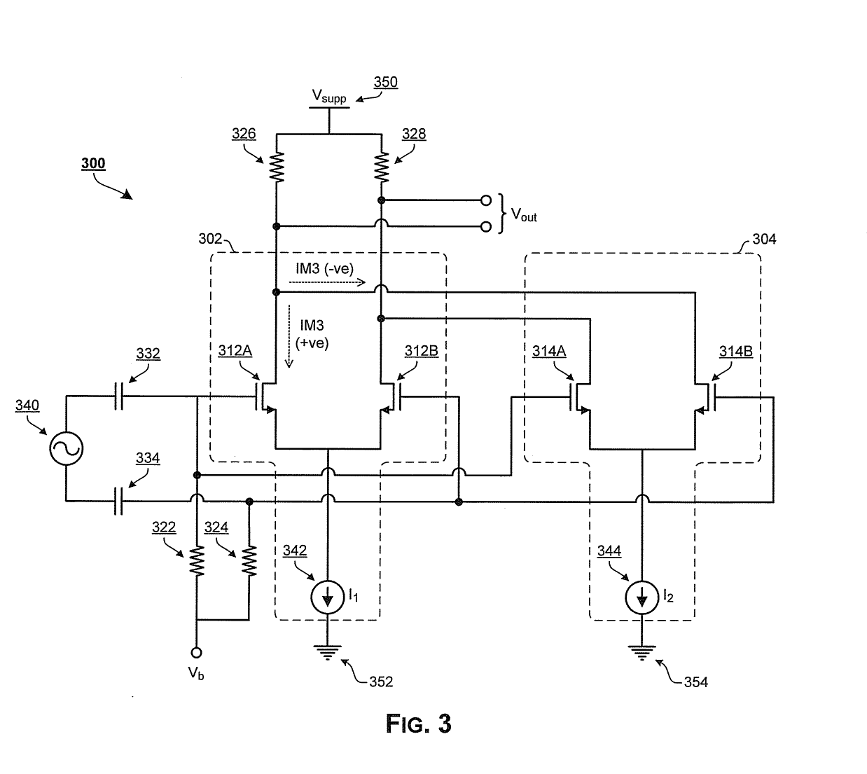

FIG. 3 is a block diagram illustrating an exemplary amplifier that may provide third-order intermodulation (IM3) cancelation, in accordance with an embodiment of the invention. Referring to FIG. 3, there is shown an amplifier 300.

The amplifier 300 may be similar to the amplifier 200, as described with respect to FIG. 2. In this regard, the amplifier 300 may be operable to amplify input signals (typically a voltage or a current) by generating output signals that match the input signal in shape but with larger amplitude. The amplifier 300 may provide third-order intermodulation (IM3) cancelation. The amplifier 300, however, may be implemented with topology in accordance with the invention which may provide the desired IM3 cancelation without causing the degradation in system perform with respect to other IM components that may result from the traditional topology described with respect to FIG. 2.

The amplifier 300 may comprise transistors 312A, 312B, 314A and 314B, resistors 322, 324, 326 and 328, capacitors 332 and 334, bias current sources I₂ 342 and I₁ 344, main voltage supply (Vₛᵤₚₚ) 350, and grounds 352 and 354. The transistors 312A, 212B, 314A and 314B may comprise n-type MOS (NMOS), p-type MOS (PMOS), or complementary MOS (CMOS) transistors.

The amplifier 300 may amplify input signals, corresponding to input voltage (Vᵢₙ) 340 for example. In this regard, the amplification performed via the amplifier 300 may comprise utilizing the Vₙ 340 in controlling adjusting output of the power supply of the amplifier 300, corresponding to the Vₛᵤₚₚ 350, such that the output may match the input signal in form but be larger in value. The capacitors 332 and 334 may be used to regulate and control inputting of signals into the amplifier 200, such as by providing DC blocking. The amplifier 300 may provide IM3 cancelation. In this regard, the amplifier 300 may be implemented as differential circuit, where the amplification and IM3 cancelation may be performed via separate branches, namely a main branch (302) for performing the main gain amplification, and an auxiliary branch (304) for providing the IM3 cancelation. The main gain branch 302 may comprise transistors 312A and 312B, and bias current sources I₁ 342. The auxiliary branch 304 may comprise transistors 314A and 314B, and bias current sources I₂ 344. The input signal, corresponding to Vᵢₙ 340, may be utilized along with bias voltage V_{b} in controlling the gates of the transistors of the main branch 302 and the auxiliary branch 304. This may be done in a manner that accounts for the differential topology of amplifier 300. For example, Vᵢₙ 340 may be coupled (through capacitor 332) to the gates of transistors 312A and 314A of the main branch 302 and the auxiliary branch 304, respectively, with the bias voltage V_{b} being applied (via resistor 322) to provide biasing. Similarly, Vᵢₙ 340 may be coupled (through capacitor 334) to the gates of transistors 312B and 314B of the main branch 302 and the auxiliary branch 304, respectively, with the bias voltage V_{b} being applied (via resistor 324) to provide biasing. In this regard, the capacitors 332 and 334, resistors 322 and 324, bias voltage V_{b}, and transistors 312A, 212B, 314A and 314B may be chosen and/or configured to enable generating the differential output voltage Vₒᵤₜ based on the Vᵢₙ 340. In this regard, the main branch 302 may provide the amplification (i.e., adjusting modulating of currents driven by Vₛᵤₚₚ 350 through resistors 326 and 328, respectively based on input signal(s) corresponding to the Vᵢₙ 340) while the auxiliary branch 304 may provide and/or enable the needed IM3 cancelation, such as by generating an IM3 distortion signal corresponding to and utilized in cancelling the IM3 component resulting from amplification performed via the main branch 320.

The IM3 cancelation may be generated differentially via the auxiliary branch 304 in an improved manner compared to the traditional topology. In this regard, the outputs of the main gain branch 302 and the auxiliary branch 304 may be connected in manner such that the IM3 component of the main branch 302 may be cancelled. For example, because differential circuit topology inherently produces IM3 with a same sign, the outputs of the main branch 302 and the auxiliary branch 304 may be cross-coupled (thus inverting the IM3 distortion signal) to enable cancelling IM3 of the main branch 302. The transistors 312A, 312B, 314A and 314B and the bias current sources I₁ (342) and I₂ (344) may be selected and/or configured adaptively, to optimize IM3 cancelation performance. In this regard, transistors 314A and 314B, and the bias current source 1₂ 342 may be chosen to provide large IM3 over a wide input signal range while producing small desired signal gain. This may result in an improved IIP3 with no (or negligible) effect on other orders of intermodulation, particularly second-order intermodulation (IM2). Accordingly, IM3 cancelation maybe performed with a differential circuit and may result in the circuit IIP2 not being degraded.

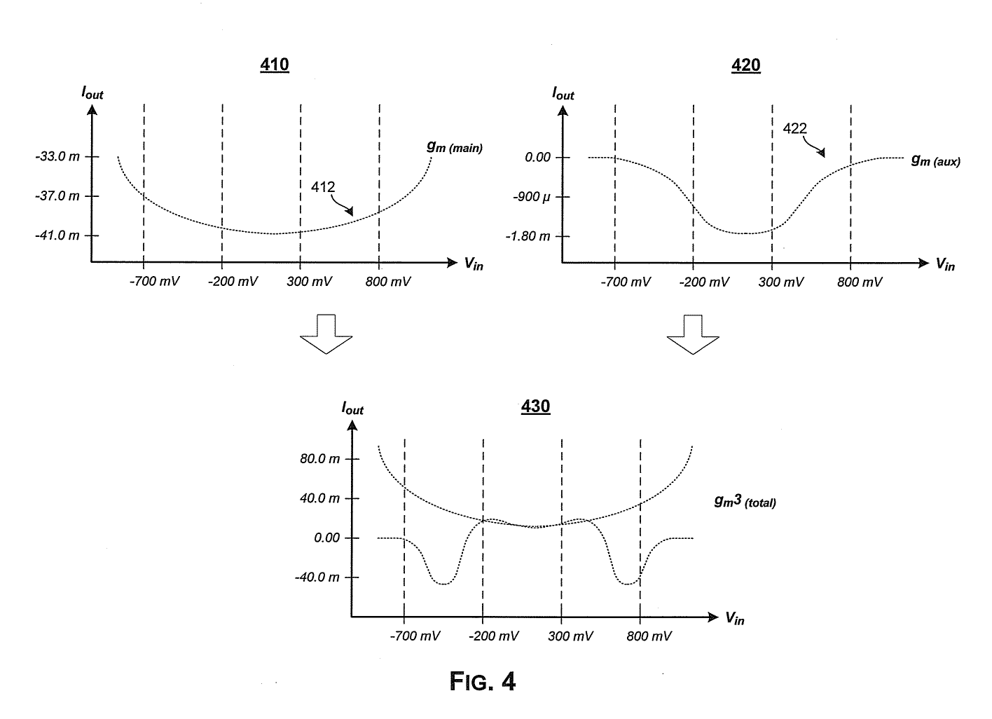

FIG. 4 is a diagram illustrating exemplary transconductance functions for main and auxiliary paths of an amplifier configured for optimized IM3 cancelation, and a corresponding total transconductance function for the amplifier, in connection with an embodiment of the invention. Referring to FIG. 4, there are shown diagrams 410, 420, and 430, illustrating exemplary transconductance (gₘ) functions—e.g., determined based on input voltage (V₁) values and corresponding output current (Iₒᵤₜ) values—for main and auxiliary paths (e.g., 302 and 304) of an amplifier (e.g., 300) configured for optimized third-order intermodulation (IM3) cancelation.

The transconductance (gₘ) of a transistor represents the ratio of the current change at the output to the voltage change at the input. In other words, the transconductance (gₘ) may be represented as derivative of Iₒᵤₜ (the y-axis) expresses as function of Vᵢₙ (x-axis). When the auxiliary path used in generating the third-order intermodulation (IM3) distortion signal is configured optimally, the auxiliary path may provide large IM3 over a wide input signal range while producing small desired signal gain. This is shown in diagrams 410 and 420, representing the transconductance (gₘ) function (412) of the main amplification path (e.g., branch 302 of amplifier 300) and the transconductance (gₘ) function (422) of the auxiliary path (e.g., branch 304 of the amplifier 300), respectively. In this regard, the auxiliary gₘ 422 may be a small fraction of the main gₘ 412—i.e., the values corresponding to auxiliary gₘ 422 (e.g., ranging between 0 and −1.8 in the Vᵢₙ range shown) are relatively small compared to the values corresponding to the main gₘ 412 (e.g., ranging between −33.0 and −41.0 in the same Vᵢₙ range)—thus, resulting in minor degradation in overall (total) gₘ. This is shown in diagram 430, representing the third-order derivative of the main and auxiliary path transfer function, expressed as third-order distortion coefficient gₘ3 (total) (thus corresponding to the third-order intermodulation cancelation processing), which shows a near perfect cancelation of IM3 resulting in enhanced IIP3 performance.

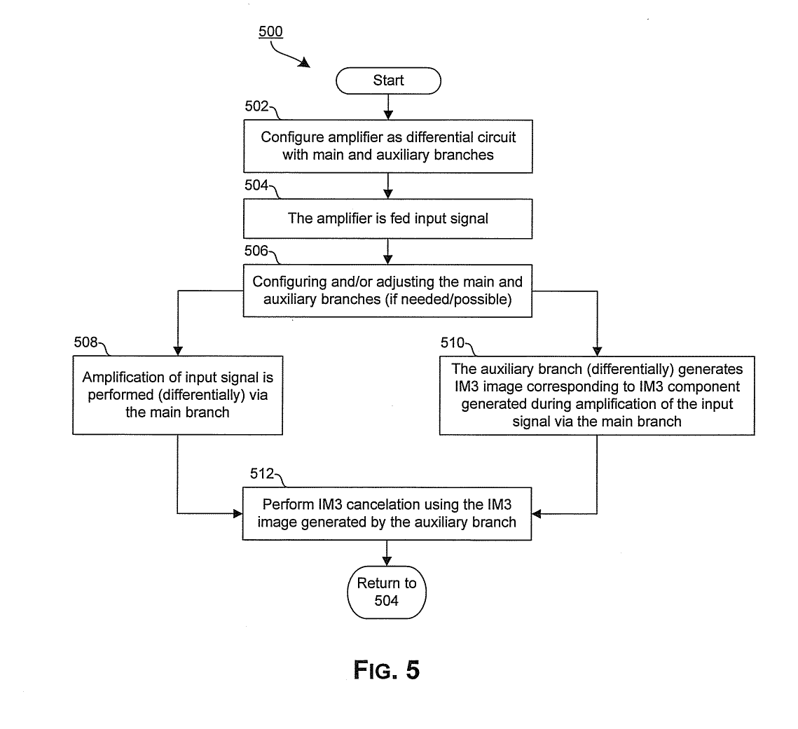

FIG. 5 is a flow chart that illustrates exemplary optimized IM3 cancelation, in accordance with an embodiment of the invention. Referring to FIG. 5, there is shown a flow chart 500 comprising a plurality of exemplary steps for an optimized IM3 cancelation in an amplifier, such as amplifier 300, for example.

In step 502, an amplifier may be constructed and/or configured as a differential circuit with main and auxiliary branches, optimized for enhanced third-order intermodulation (IM3) cancelation. This may be done at design and/or manufacturing time, but it may also comprise additional configuration and/or adjustment during operation of the amplifier. For example, an amplifier may be structured and/or designed with the similar topology as amplifier 300, for example. This may comprise selecting (or configuring) particular transistor elements (e.g., transistors 312A, 312B, 314A and 314B), resistors, and/or any other elements of the amplifier (e.g., bias voltage and/or current sources). In step 504, an input signal may be fed into the amplifier (e.g., the input signal may correspond to Vᵢₙ 340 of the amplifier 300). In step 506, the main and auxiliary branches (302 and 304) of the amplifier (300) may be configured and/or adjusted (if needed and/or possible). This may comprise, for example, setting and/or adjusting the bias voltage V_{b}, and/or the bias current sources 342 and/or 344.

In step 508, the amplification of an input signal may be performed (differentially) via the main branch (302). In step 510, the auxiliary branch 304 may generate (differentially) an IM3 distortion signal corresponding to IM3 component generated during amplification of the input signal via the main branch (302). In step 512, the IM3 cancelation may be performed using the IM3 distortion signal generated by the auxiliary branch. In this regard, the cancelation may be achieved by cross-coupling the outputs of the main branch (302) and the auxiliary branch (304), to invert the sign of the IM3 distortion signal, which is equal in value to the IM3 components generated in the main branch (302). The process may then loop back to step 504—the handling additional input signal(s).

Various embodiments of the invention may comprise a method and system for improving linearity of an amplifier by means of third-order intermodulation (IM3) cancelation. The amplifier 300 may be used in providing improved third-order intermodulation (IM3) cancelation. The amplifier 300 may comprise the main branch 302, configured for amplifying input signals, and the auxiliary branch 304, configured for generating IM3 signals which may be equal in value to corresponding IM3 components resulting when amplifying input signals via the main branch 302. The amplifier 300 as a whole, and each of the main branch 302 and the auxiliary branch 304, may be configured in accordance with differential circuit topology. In this regard, the differential circuit topology may result in the auxiliary branch 304 being operable to generate IM3 distortion signals with minimal (or no) non-IM3 signals, especially signals that may affect second-order intercept point (IIP2) processing. Sign of IM3 distortion signals generated via the auxiliary branch 304 may be inverted to provide the desired IM3 cancelation. In this regard, outputs of the main branch 302 and the auxiliary branch 304 may be cross-coupled, to invert the sign of the IM3 distortion signals generated via the auxiliary branch 304. Each of the main branch 302 and the auxiliary branch 304 may comprise at least two transistor elements, such as transistors 312A and 312B for the main branch 302 and the transistors 314A and 314B for the auxiliary branch 304. In this regard, transistors 312A, 312B, 314A and 314B may comprise NMOS transistors, PMOS transistors, and/or CMOS transistors. In addition, separate bias current sources (342 and 344) may be applied to each of the main branch 302 and the auxiliary branch 304. The transistors and/or the bias current source used in each of the main branch 302 and the auxiliary branch 304 (e.g., transistors 312A and 312B and bias current sources 342 used in the main branch 302, and transistors 314A and 314B and bias current sources 344 used in the auxiliary branch 304) may be selected adaptively, such as to ensure the optimal IM3 cancelation performance with the least impact on non-IM3 performance in the amplifier 300. Operation of the auxiliary branch 304 may also be adaptively controlled by adjusting one or more components of the amplifier 300, such as by adjusting one or both of the bias current sources (342 and 344) for example.

Other embodiments of the invention may provide a non-transitory computer readable medium and/or storage medium, and/or a non-transitory machine readable medium and/or storage medium, having stored thereon, a machine code and/or a computer program having at least one code section executable by a machine and/or a computer, thereby causing the machine and/or computer to perform the steps as described herein for improving linearity of an amplifier by means of IM3 cancelation.

Accordingly, the present invention may be realized in hardware, software, or a combination of hardware and software. The present invention may be realized in a centralized fashion in at least one computer system, or in a distributed fashion where different elements are spread across several interconnected computer systems. Any kind of computer system or other system adapted for carrying out the methods described herein is suited. A typical combination of hardware and software may be a general-purpose computer system with a computer program that, when being loaded and executed, controls the computer system such that it carries out the methods described herein.

The present invention may also be embedded in a computer program product, which comprises all the features enabling the implementation of the methods described herein, and which when loaded in a computer system is able to carry out these methods. Computer program in the present context means any expression, in any language, code or notation, of a set of instructions intended to cause a system having an information processing capability to perform a particular function either directly or after either or both of the following: a) conversion to another language, code or notation; b) reproduction in a different material form.

While the present invention has been described with reference to certain embodiments, it will be understood by those skilled in the art that various changes may be made and equivalents may be substituted without departing from the scope of the present invention. In addition, many modifications may be made to adapt a particular situation or material to the teachings of the present invention without departing from its scope. Therefore, it is intended that the present invention not be limited to the particular embodiment disclosed, but that the present invention will include all embodiments falling within the scope of the appended claims.

What is claimed is:

1. A method, comprising:
amplifying an input signal via an amplifier circuit, the amplifying comprising third-order intermodulation (IM3) cancelation, wherein said IM3 cancelation comprises:
generating via a secondary branch of the amplifier circuit, a secondary IM3 signal that is equal to an IM3 signal resulting from amplifying the input signal via a main branch of the amplifier circuit; and
configuring said secondary branch to reduce non-IM3 signals resulting during said generation of said secondary IM3 signal, wherein said non-IM3 signals comprise signals affecting second-order Input Intercept Point (IIP2) processing.

2. The method according to claim 1, comprising configuring said secondary branch for operation as differential gain path.

3. The method according to claim 2, wherein said secondary branch comprises a plurality of transistors and a bias current source configured for said operation as differential gain path.

4. The method according to claim 3, comprising adaptively selecting and/or configuring said plurality of transistors and said bias current source.

5. The method according to claim 3, wherein said plurality of transistors comprises NMOS transistor elements, PMOS transistor elements, and/or CMOS transistor elements.

6. The method according to claim 3, comprising applying main bias current source to the main path.

7. The method according to claim 6, comprising controlling operation of said secondary path by adjusting one or both of said bias current source and said main bias current source.

8. The method according to claim 1, comprising cross-coupling outputs of said main branch and said secondary branch.

9. A system, comprising:
one or more circuits for use in an electronic device for amplifying input signals, wherein the amplifying comprises third-order intermodulation (IM3) cancelation, the one or more circuits being operable to:
generate via a secondary amplification circuit, a secondary IM3 signal that is equal to an IM3 signal generated via a main amplification circuit; and
configure said secondary amplification circuit to reduce non-IM3 signals resulting from said generation of said secondary IM3 signal, wherein said non-IM3 signals comprise signals affecting second-order Input Intercept Point (IIP2) processing.

10. The system according to claim 9, wherein said secondary amplification circuit is configured for operation as differential gain path.

11. The system according to claim 10, wherein said secondary amplification circuit comprises a plurality of transistors and a bias current source for enabling said operation of said secondary amplification circuit as differential gain path.

12. The system according to claim 11, comprising adaptively selecting said plurality of transistors and said bias current source.

13. The system according to claim 11, wherein said plurality of transistors comprises NMOS transistor elements, PMOS transistor elements, and/or CMOS transistor elements.

14. The system according to claim 11, wherein the main amplification circuit comprises main bias current source.

15. The system according to claim 14, wherein said one or more circuits are operable to control operation of said secondary amplification circuit by adjusting one or both of said bias current source and said main bias current source.

16. The system according to claim 9, comprising cross-coupling outputs of said main amplification circuit and said secondary amplification circuit.

17. A system, comprising:
an amplifier circuit that is operable to perform third-order intermodulation (IM3) cancelation, wherein said amplifier circuit comprises:
a main branch for amplifying an input signal, said main branch comprising at least two transistor elements;
a secondary branch for generating a secondary IM3 signal that is equal to an IM3 signal resulting from amplifying said input signal via said main branch, said secondary branch comprising at least two transistor elements, wherein said secondary branch is configured to reduce non-IM3 signals resulting during said generation of said secondary IM3 signal;
a first bias current source applied to said main branch; and
a second bias current source applied to said secondary branch.

18. The system according to claim 17, wherein said non-IM3 signals comprise signals degrading second-order Input Intercept Point (IIP2) processing.

19. The system according to claim 17, comprising controlling operation of said secondary branch by adjusting one or both of said first bias current source and said second bias current source.

20. The system according to claim 17, wherein outputs of said main branch and said secondary branch are cross-coupled to invert a sign of said secondary IM3 signal generated via said secondary branch relative to said IM3 signal resulting from amplifying said input signal via said main branch.
